(19) United States
(12) Patent Application Publication
(10) Pub. No.: US 2025/0239564 A1
(43) Pub. Date: Jul. 24, 2025

(54) TREATMENT PROCESS FOR WAFER BONDING PROCESSES

(71) Applicant: Taiwan Semiconductor Manufacturing Co., Ltd., Hsinchu (TW)

(72) Inventors: Ming-Tsu Chung, Hsinchu (TW); Yung-Chi Lin, Su-Lin City (TW); Yan-Zuo Tsai, Hsinchu (TW); Yang-Chih Hsueh, Hsinchu (TW)

(21) Appl. No.: 18/663,915

(22) Filed: May 14, 2024

Related U.S. Application Data
(60) Provisional application No. 63/624,519, filed on Jan. 24, 2024.

(51) Int. Cl. H01L 23/00

(52) U.S. Cl. CPC H01L 24/80; H01L 24/08; H01L 24/94; H01L 24/13; H01L 2224/08145; H01L 2224/13147; H01L 2224/13155; H01L 2224/13164; H01L 2224/13166; H01L 2224/80009; H01L 2224/80357; H01L 2224/80379; H01L 2224/80896; H01L 2224/94; H01L 2924/04642; H01L 2924/04941; H01L 2924/05042; H01L 2924/0534; H01L 2924/059

(57) ABSTRACT

A method includes performing a plasma treatment on a first wafer, performing a treatment process on the first wafer, wherein the treatment process results in the first wafer to be more hydrophobic than before the treatment process, pre-bonding the first wafer to a second wafer through wafer-to-wafer bonding, and performing an annealing process to bond the first wafer to the second wafer.

### PRIORITY CLAIM AND CROSS-REFERENCE

This application claims the benefit of the following provisionally filed U.S. patent application: Application No. 63/624,519, filed on Jan. 24, 2024, and entitled “Semiconductor device and method of manufacturing the same,” which application is hereby incorporated herein by reference.

### BACKGROUND

Fusion bonding and hybrid bonding are common bonding schemes for bonding two package components such as wafers and/or dies to each other. In the bonding process, the package components are first bonded through pre-bonding at a lower temperature, and then an anneal process is performed at a higher temperature to bond the package components together.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 illustrate the cross-sectional views of intermediate stages in the formation of a package including a bonding process in accordance with some embodiments.

FIG. 7 illustrates a bonding scheme including two bond pads and dielectric layers in accordance with some embodiments.

FIGS. 8, 9, and 10 illustrate the peak concentrations of carbon, nitrogen, and oxygen at bond interfaces of different bond layers in accordance with some embodiments.

FIG. 11 illustrates a device wafer bonding to a carrier wafer in accordance with some embodiments.

FIG. 12 illustrates a carrier wafer bonding to a reconstructed wafer in accordance with some embodiments.

FIG. 13 illustrates a reconstructed wafer bonding to a device wafer in accordance with some embodiments.

FIG. 14 illustrates the bonding of two device wafers in accordance with some embodiments.

FIG. 15 illustrates the bonding of two reconstructed wafers in accordance with some embodiments.

FIG. 16 illustrates the treatment of a wafer using Hexamethyldisilazane (HMDS) in accordance with some embodiments.

FIG. 17 illustrates the treatment of a wafer using Aminopropyltriethoxysilane (APTES) in accordance with some embodiments.

FIG. 18 illustrates the treatment of a wafer using (3-mercaptopropyl) trimethoxysilane (MPTMS) in accordance with some embodiments.

FIGS. 19-22 illustrate the patterns and positions of treated regions in wafers in accordance with some embodiments.

FIG. 23 illustrates a process flow for forming a package including in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of performing surface treatment on wafers to prepare the wafers for bonding, and the resulting structure are provided. In accordance with some embodiments of the present disclosure, a surface treatment is performed on a wafer using a chemical, so that the surface of the wafer is modified from a hydrophilic surface to a hydrophobic surface. Since the bond wave speed on the wafers having hydrophilic surfaces is high during pre-bonding, distortion may occur and is more severe. In the embodiments of the present disclosure, the treatment modifies the hydrophilic surfaces as hydrophobic surfaces, and the bond wave speed and the distortion are reduced.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

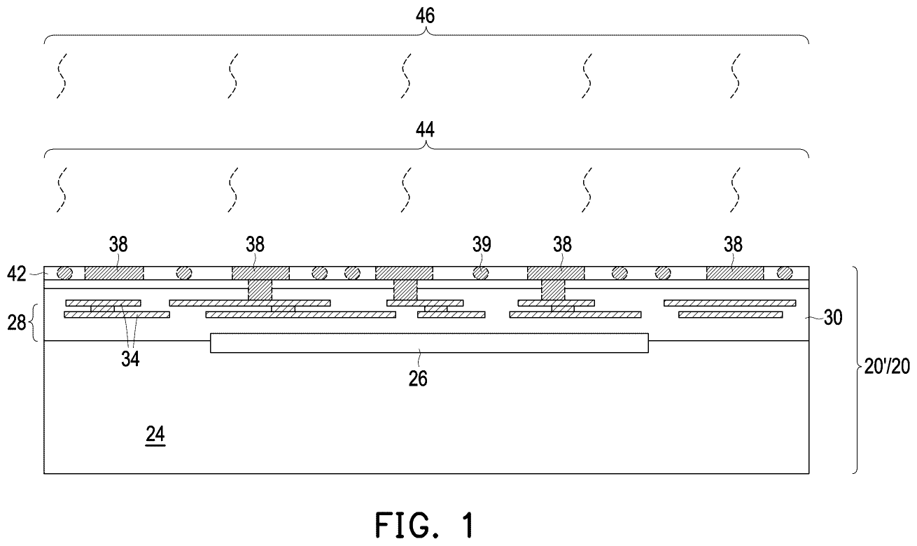

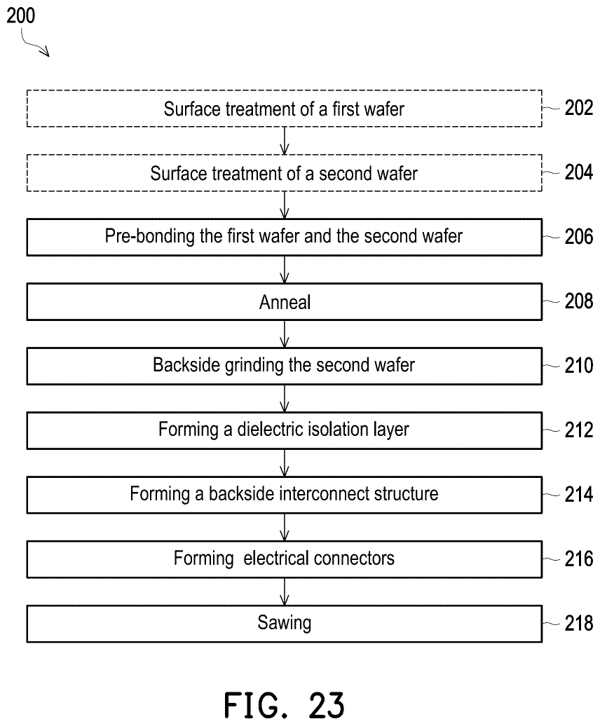

FIGS. 1 through 6 illustrate the cross-sectional views of intermediate stages in the formation of a package with treated surfaces in accordance with some embodiments of the present disclosure. The corresponding processes are also reflected schematically in the process flow shown in FIG. 23.

FIG. 1 illustrates a cross-sectional view of wafer 20. In accordance with some embodiments, wafer 20 is or comprises a device wafer including active devices and possibly passive devices, which are represented as integrated circuit devices 26. Wafer 20 may include a plurality of dies 20′ therein, with the details of one of dies 20′ being illustrated. In accordance with alternative embodiments, wafer 20 is a carrier wafer, which may include a silicon wafer (which is free from metal features and active devices therein) and a bond layer thereon.

In accordance with alternative embodiments, wafer 20 is an interposer wafer, which is free from active devices, and may or may not include passive devices. In accordance with yet alternative embodiments, wafer 120 is or comprises a reconstructed wafer including device dies packaged therein, with the device dies being encapsulated in an encapsulant(s) such as a molding compound.

In subsequent discussion, a device wafer 20 is used as an example. The embodiments may also be applied on other types of wafers as discussed above.

In accordance with some embodiments, wafer 20 includes semiconductor substrate 24 and the features formed at a top surface of semiconductor substrate 24. Semiconductor substrate 24 may be formed of or comprise crystalline silicon, crystalline germanium, crystalline silicon germanium, carbon-doped silicon, a III-V compound semiconductor, or the like. Semiconductor substrate 24 may also be a bulk semiconductor substrate or a Semiconductor-On-Insulator (SOI) substrate.

In accordance with some embodiments, wafer 20 includes integrated circuit devices 26, which are formed at the top surface of semiconductor substrate 24. Integrated circuit devices 26 may include Complementary Metal-Oxide Semiconductor (CMOS) transistors, resistors, capacitors, diodes, and/or the like in accordance with some embodiments. The details of integrated circuit devices 26 are not illustrated herein.

Interconnect structure 28 is formed over semiconductor substrate 24. In accordance with some embodiments, interconnect structure 28 includes a plurality of dielectric layers 30, and a plurality of conductive features 34 in the dielectric layers 30. The dielectric layers 30 may include an Inter-Layer Dielectric (ILD) that fills the spaces between the gate stacks of transistors in integrated circuit devices 26 (if formed). In accordance with some embodiments, the ILD is formed of silicon oxide, silicon nitride, silicon oxynitride, Phospho Silicate Glass (PSG), Boro Silicate Glass (BSG), Boron-doped Phospho Silicate Glass (BPSG), Fluorine-doped Silicate Glass (FSG), or the like. The ILD may be formed using spin-on coating, Flowable Chemical Vapor Deposition (FCVD), Chemical Vapor Deposition (CVD), or the like.

The conductive features 34 may include metal lines and vias. When wafer 20 includes integrated circuit devices 26, the conductive features 34 may also be connected to the integrated circuit devices 26 (if formed). The metal lines at a same level are collectively referred to as a metal layer hereinafter. In accordance with some embodiments, interconnect structure 28 includes a plurality of metal layers interconnected through the vias. The metal lines and vias may be formed of copper, a copper alloy, and/or another metal.

Interconnect structure 28 may also include a passivation layer, which may be formed of a non-low-k dielectric material, over the low-k dielectric layers. The passivation layer may be formed of or comprise Undoped Silicate Glass (USG), silicon nitride, silicon oxide, or the like, or multi-layers thereof. There may also be metal pads (such as aluminum-copper pads), Post Passivation Interconnect (PPI), or the like, which are referred to as conductive features.

In accordance with some embodiments, bond pads 38 are formed at the top surface of wafer 20. Bond pads 38 may be formed through plating, and have vertical and straight sidewalls. In accordance with alternative embodiments in which fusion bond is to be performed, bond pads 38 are not formed. Accordingly, bond pads 38 are illustrated as being dashed to indicate that bond pads 38 may or may not be formed.

Further referring to FIG. 1, bond layer 42 is deposited over interconnect structure 28. The top surface of bond layer 42 is coplanar with the top surfaces of bond pads 38. This is achieved by performing a Chemical Mechanical Polish (CMP) process in the formation of bond pads 38 when bond pads 38 are formed. When bond pads 38 are not formed, the CMP process may or may not be performed. In accordance with some embodiments, bond layer 42 may be formed of a silicon-base dielectric material, which may comprise one or more of oxygen, carbon, and nitrogen. For example, bond layer 42 may be formed of or comprise SiON, SiN, SiOCN, SiCN, SiOC, SiC, TIN, TiO, or the like. After the CMP process, wafer 20 is cleaned, for example, using Deioned (DI) water. The CMP process and the cleaning using ID wafer are also referred to as a wet process.

In accordance with some embodiments, a plasma treatment process 44 may be performed on the top surface of wafer 20. In accordance with some embodiments, the plasma treatment process 44 is performed by generating plasma from a process gas, and treating the top surface of wafer 20 with the plasma. In accordance with some embodiments, the process gas may comprise nitrogen (N₂), oxygen (O₂), argon, He, H₂, NH₃, or the combinations thereof such as the mixture of N₂ and H₂ (denoted as N₂/H₂), H₂/He, N₂/He, or the like. The treatment may be performed with or without applying a bias power. Through the plasma treatment process 44, dangling bonds are generated on the top surface of wafer 20.

In accordance with some embodiments, after the plasma treatment process 44, wafer 20 may be exposed to water/moisture, for example, through a rinse process, so that the dangling bonds of silicon atoms may form Si—OH bonds at the surface of wafer 20.

The wet process (including the CMP process) and the plasma treatment process 44 may cause the top surface of wafer 20 to be hydrophilic. In the subsequently performed per-bonding process, when hydrophilic surfaces of two wafers are in contact with each other, the respective bond wave may have a too high propagation speed, causing distortion. In accordance with some embodiments, as shown in FIG. 1, treatment process 46 is performed using a chemical to convert the hydrophilic surface into a hydrophobic surface. The respective process is illustrated as process 202 in the process flow 200 as shown in FIG. 23.

In accordance with some embodiments, the treatment process 46 is performed using a chemical selected from Hexamethyldisilazane (HMDS, with the linear formula being ([(CH₃)₃Si]₂NH), Aminopropyltriethoxysilane (APTES, with the linear formula being H₂N(CH₂)₃Si(OC₂H₅)₃), (3-mercaptopropyl) trimethoxysilane (MPTMS, with the linear formula being HS(CH₂)₃Si(OCH₃)₃), and the like, or combinations thereof. The circles 39 at the surface of wafer 20 represent the treatment process 46 has been performed, and represent the functional groups of the treatment chemical attached to the surface of wafer 20.

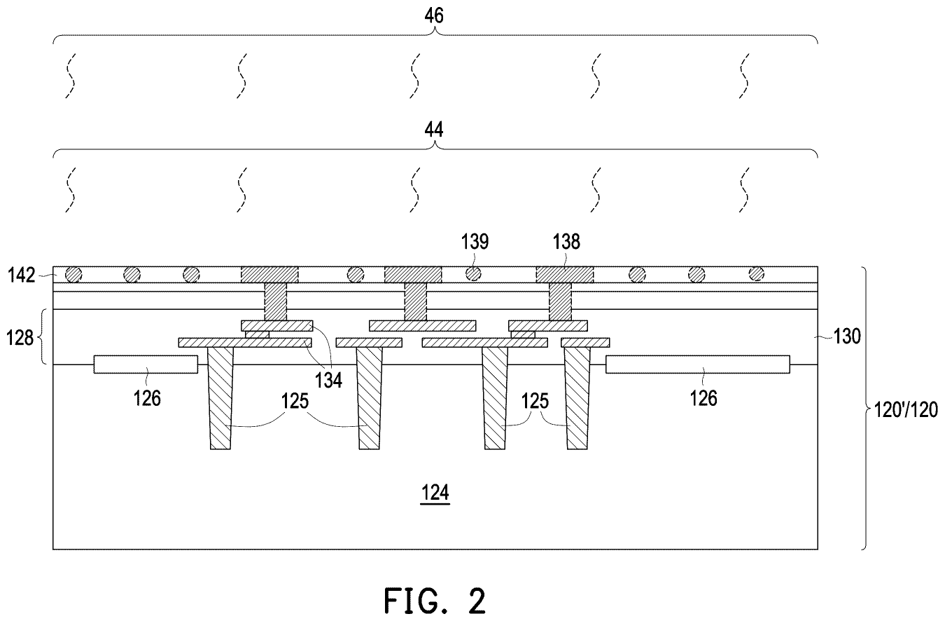

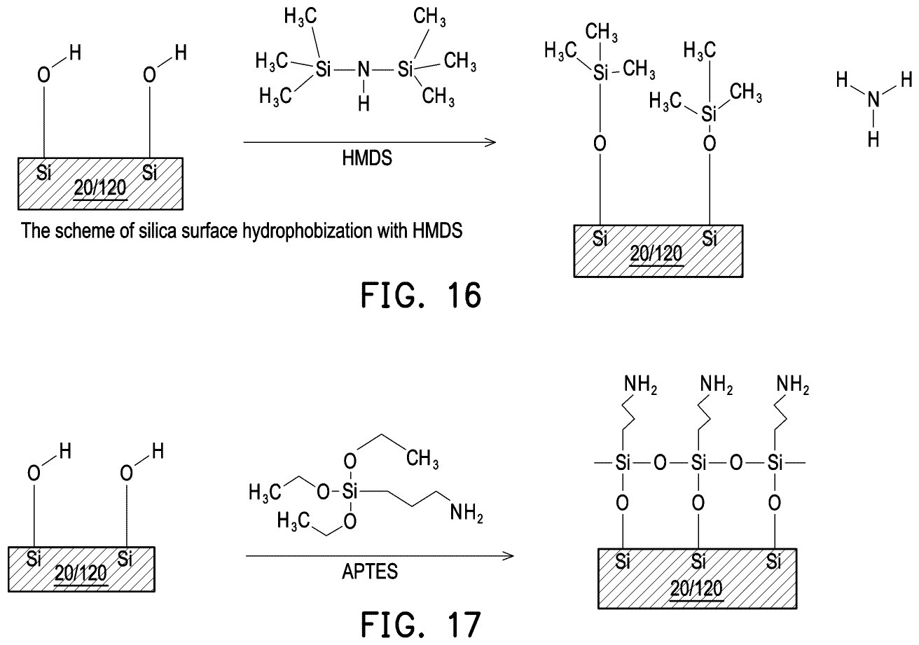

FIG. 16 illustrates an example process for treating wafer 20 using HMDS in accordance with some embodiments. The wafer is denoted as wafer 20/120 to indicate that at least one, or both of, wafer 20 and wafer 120 (FIG. 2) may be treated. In subsequent discussion, the treatment of wafer 20 is used as an example. The surface of wafer 20 have OH groups, which are joined to the silicon atoms in the bond layer 42 (FIG. 1). The wafer 20 may be at room temperature, for example, in the range between about 18° C. and about 22°. Next, HMDS is conducted to wafer 20, for example, in the form of hot steam. The temperature of the hot steam may be in the range between about 100° C. and about 150° C. The duration that wafer 20 is exposed to the hot HMDS steam may be in the range between about 5 seconds and about 600 seconds.

The wafer 20 may then be cooled down, for example, by contacting the back surface of wafer 20 to a cold plate that is at the room temperature. The cooling down time may be in the range between about 5 seconds and about 600 seconds. Through the exposure to the hot HMDS steam, the OH groups are broken, and the functional groups Si—CH₃ in the HMDS are attached to the Si—O bonds. The resulting wafer 20 include silicon atoms bonded with CH₃ group. This creates a hydrophobic surface.

FIG. 17 illustrates an example process for treating wafer 20 (or wafer 120) using APTES in accordance with some embodiments. The surface of wafer 20 also have OH groups, which are joined to the silicon atoms in the bond layer 42 (FIG. 1). The wafer 20 may be at room temperature, for example, in the range between about 18° C. and about 22°. Next, hot APTES steam is conducted, with the wafer 20 being exposed to the APTES steam. The hot steam may be generated from the solution having ethanol and water, with the APTES dissolved therein to generate the solution. The temperature of the steam may be in the range between about 100° C. and about 200° C. The duration that wafer 20 is exposed to the hot steam may be in the range between about 5 seconds and about 600 seconds.

The wafer 20 may then be cooled down, for example, by contacting the back surface of wafer 20 to a cold plate that is at the room temperature. The cooling down time may be in the range between about 5 seconds and about 600 seconds. Through the exposure to the hot APTES steam, the OH groups are broken, and the functional groups NH₂ are attached to the Si—O bonds, as shown in FIG. 17. This creates a hydrophobic surface.

In accordance with alternative embodiments in which the treatment chemical comprises APTES, the following processes may be performed. The wafer 20 may first have its back surface in contact with a hot plate to remove water (if any) from its surface through evaporation. The hot plate may have a temperature in the range between about 100° C. and about 150° C. The duration may be in the range between about 5 seconds and about 600 seconds.

The wafer 20 may then be placed in a solution including APTES dissolved in a solvent. The solvent may include anhydrous toluene, methanol, ethanol, hexane, deionized water, or the like, or combinations thereof. The solution may be at a temperature in the range between about 20° C. and about 100°. The wafer 20 is placed in the solution for a duration in the range between about 5 seconds and about 600 seconds. Wafer 20 is then rinsed, for example, using a solvent(s) including toluene, methanol, ethanol, hexane, deionized water, and/or the like, so that the APTES on wafer 20 is removed.

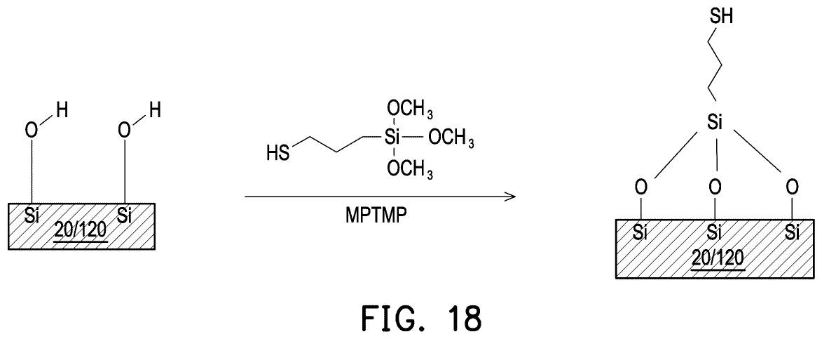

FIG. 18 illustrates an example process for treating wafer 20 using MPTMS in accordance with some embodiments. The surface of wafer 20 have OH groups, which are joined to the silicon atoms in the bond layer 42 (FIG. 1). The wafer 20 may first have its back surface in contact with a hot plate to remove water (if any) from its surface through evaporation. The hot plate may have a temperature in the range between about 100° C. and about 150° C. The duration may be in the range between about 5 seconds and about 600 seconds.

The wafer 20 may then be placed into a solution including MPTMS dissolved in a solvent. The solvent may include anhydrous toluene, methanol, ethanol, hexane, deionized water, or combinations thereof. The solution may be at a temperature in the range between about 20° C. and about 100°. The wafer is placed in the solution for a duration in the range between about 5 seconds and about 600 seconds. Wafer 20 is then rinsed, for example, using a solvent(s) including toluene, methanol, ethanol, hexane, deionized water, and/or the like, so that the MPTMS on wafer 20 is removed.

Referring back to FIG. 1, the treatment process 46 may be performed on the entire top surface of wafer 20, and/or on selected regions of wafer 20. When performed on entire wafer 20, the treatment process has the function of slowing down the bond wave propagation on the entire surface of wafer 20. When performed on selective (but not all) portions of wafer 20, the treatment process 44 has the function of slowing down the bond wave speed of the selective portions of wafer 20 where the bond wave speed is higher than the untreated portions of wafer 20. The resulting effect may be that the bond wave may propagate from the center of wafer 20 to edges of wafer at a uniform speed, and the bond wave at any moment may be close to a perfect circle as much as possible.

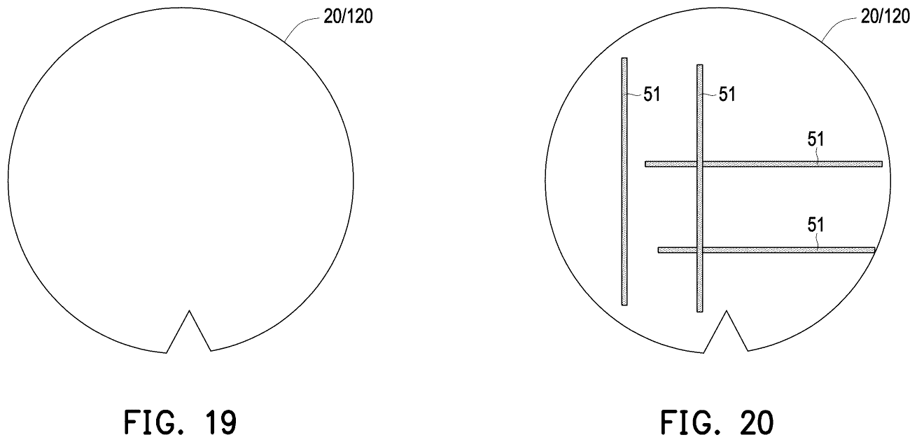

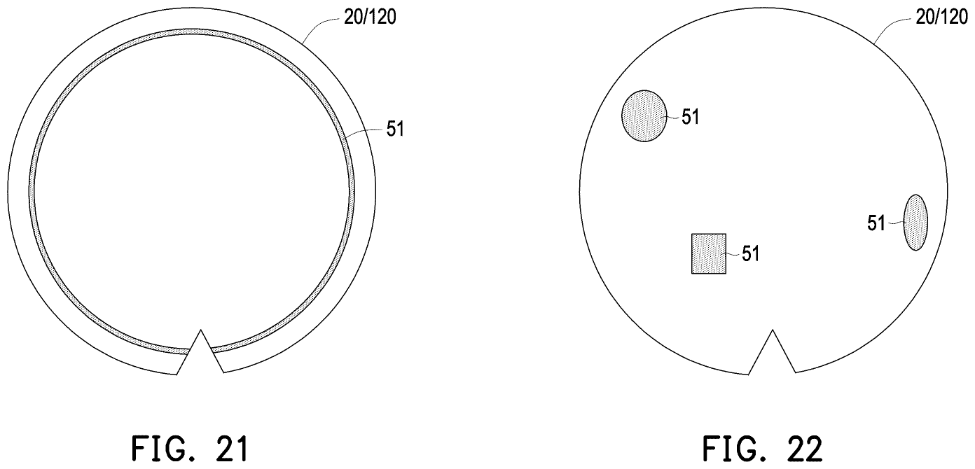

FIGS. 19-22 illustrate some wafers and the treated portions (by treatment process 46) in accordance with some embodiments. As shown in FIG. 19, the entire wafer 20/120 (with wafer 120 being treated in the process shown in FIG. 2) is treated globally by treatment process 46. In FIG. 20, some strip portions 51 of carrier wafer 20/120 are treated by treatment process 46, while the remaining portions are not treated. The overlapped regions of the treated strip portions 51 having lengthwise directions in the X-direction may overlap the treated strip portions 51 having lengthwise directions in the Y-direction. FIG. 21 illustrates an embodiment in which a circular portion 51 (or a plurality of circular regions) is treated by treatment process 46, while the remaining portions are not treated. FIG. 22 illustrates an embodiment in which selected and isolated portions 51 are treated by treatment process 46, while the remaining portions are not treated.

In accordance with some embodiments, the selective treatment process 46 is performed by forming a mask (such as a photoresist) on wafer 20/120, patterning the mask to reveal the portions of the surface to be treated, while leaving other portions covered by the mask. The treatment process 46 is then performed, as discussed above. The mask may then be removed.

In accordance with some embodiments, when HMDS is used, the wafers may be treated globally (as shown in FIG. 19) or locally (as shown in FIGS. 20 through 22). When APTES and MPTMS are used, the global treatment is performed, while no localized treatment is performed.

FIG. 2 illustrates the formation and the treatment of wafer 120 in accordance with some embodiments. Wafer 120 may also be selected from a device wafer, a reconstructed wafer, an interposer wafer, a carrier, or the like. In the illustrated example, a device wafer is illustrated as an example. In accordance with some embodiments, wafer 120 has a similar structure as that of wafer 20. The structures and the materials of the features in wafer 120 may be found referring to the like features in wafer 20, with the like features in wafer 120 being denoted by adding number “1” in front of the reference numbers of the corresponding features in wafer 20. For example, the substrate in wafer 20 is denoted as 24, and accordingly, the substrate in wafer 120 is denoted as 124.

In accordance with some embodiments, wafer 120 includes through-vias 125 (also referred to as a through-silicon vias (TSVs) or through-semiconductor vias (also TSVs)), which extend from the top surface to an intermediate level between a top surface and a bottom surface of semiconductor substrate 124.

Wafer 120 may include device dies 120′, and include integrated circuit devices 126, interconnect structure 128, bond pads 138, and bond layer 142. The details of these features may be similar to the corresponding features in wafer 20, and are not repeated herein. In accordance with some embodiments, treatment process 44, treatment process 46, or both of treatment processes 44 and 46 are performed on wafer 120. The respective process is illustrated as process 204 in the process flow 200 as shown in FIG. 23. The details of the treatment process 44 and treatment process 46 may be selected from the same group of candidate processes for treating wafer 20, and the details are not repeated herein.

In accordance with some embodiments, wafer 20 is treated by treatment process 46, and wafer 120 is not treated by treatment process 46. In accordance with alternative embodiments, wafer 120 is treated by treatment process 46, and wafer 20 is not treated by treatment process 46. In accordance with yet alternative embodiments, both of wafer 20 and 120 are treated by treatment process 46. The circles 139 at the surface of wafer 120 represent the treatment process 46 has been performed, and represent the functional groups of the treatment chemical attached to the surface of wafer 120.

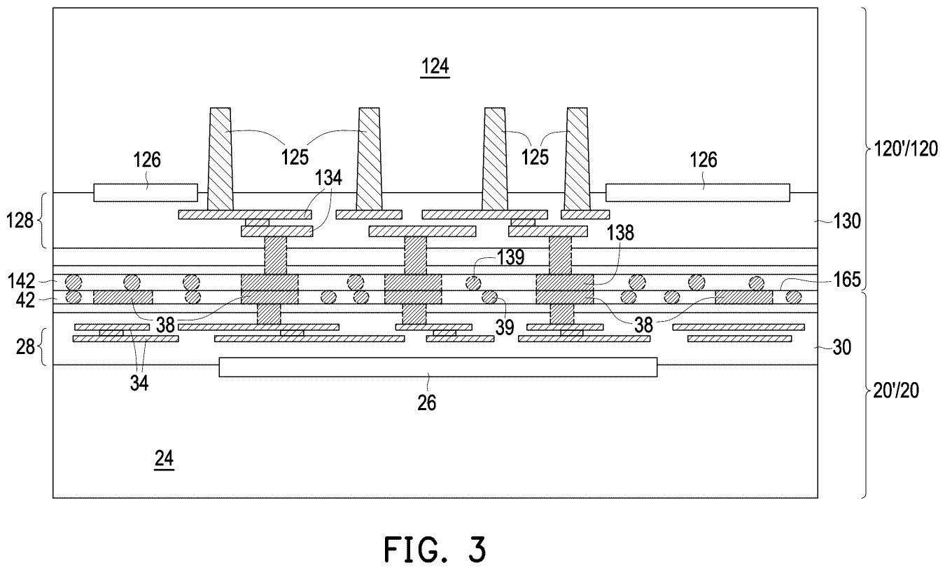

In a subsequent process, as shown in FIG. 3, wafer 120 is flipped upside down, and is bonded to wafer 20. In the illustrated example, a hybrid bonding process is performed, so that bond pads 38 are bonded to bond pads 138 through metal-to-metal bonding, and bond layer 42 is bonded to bond layer 142 through fusion bonding (with Si—O—Si bonds being formed). In accordance with alternative embodiments, other types of bonding such as fusion bonding may be performed, with no metal-to-metal bonding performed.

The wafer-bonding process includes a pre-bonding process. The respective process is illustrated as process 206 in the process flow 200 as shown in FIG. 23. In accordance with some embodiments, during the pre-bonding, wafer 120 is put into contact with wafer 20, with a pressing force applied to press wafers 20 and 120 against each other. The pre-bonding may be performed at room temperature (between about 20° C. and about 25° C.), and a higher temperature may also be used.

The pre-bonding may start from putting the center of wafer 120 into contact with the center of wafer 20. The contacting propagates from the contacting point to the edges of wafers 20 and 120, which propagation generates a bond wave propagating from the contacting point to the edges. With the bond wave propagating from the contacting point to the edges, the air between wafers 20 and 120 is gradually squeezed out, so that no air bubble or moisture is trapped between wafers 20 and 120.

In accordance with some embodiments, by performing the treatment process 46 on one or both of wafers 20 and 120, the bond wave speed, which is the propagation speed of the bond wave, is reduced. This allows for the bond wave propagation to be more uniform in different directions, and the distortion is reduced. It also reduces the trapping of air bubble or moisture.

After the pre-bonding process, an annealing process is performed. Si—O—Si bonds are thus formed between bond layers 42 and 142, so that bond layers 42 and 142 are bonded to each other. The respective process is illustrated as process 208 in the process flow 200 as shown in FIG. 23. In accordance with some embodiments, the annealing process is performed at a temperature in the range between about 250° C. and about 300° C. The annealing duration may be in the range between about 5 minutes and about 30 minutes in accordance with some embodiments. Wafer 20 and 120 are thus bonded to each other to form bonding interface 165.

Next, a backside grinding process is performed on the substrate 124 of wafer 120 a, for example, through a Chemical Mechanical Polish (CMP) process or a mechanical polish process, until through-vias 125 are exposed. The respective process is illustrated as process 210 in the process flow 200 as shown in FIG. 23.

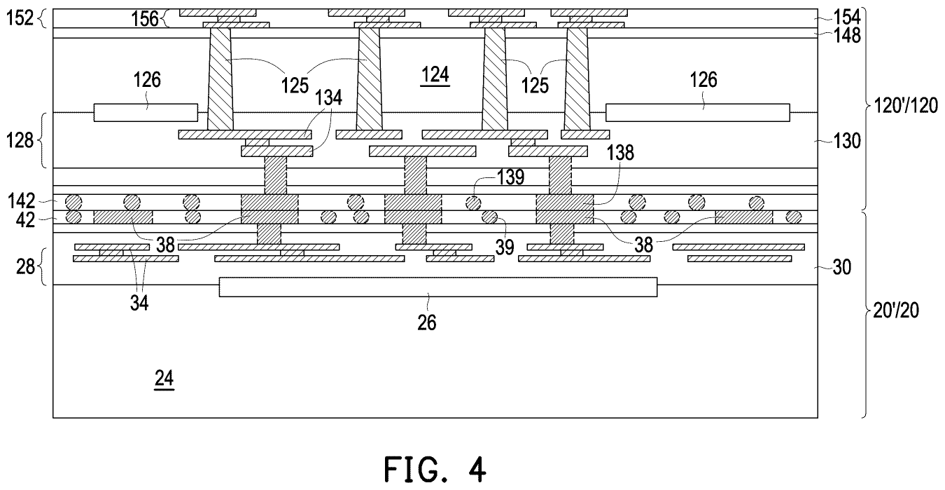

Next, as shown in FIG. 4, the semiconductor substrate 124 in wafer 120 may be recessed in an etching process, so that the top portions of TSVs 125 protrude over semiconductor substrate 124. Dielectric isolation layer 148 may then be formed to encircle the top portions of TSVs 125. The respective process is illustrated as process 212 in the process flow 200 as shown in FIG. 23. The formation of dielectric isolation layer 148 may include a deposition process to deposit a dielectric layer onto semiconductor substrate 124, so that the protruding portions of TSVs 125 are in the dielectric layer, followed by a planarization process. The portions of the dielectric layer over TSVs 125 are removed, and the remaining portions of the dielectric layer form the dielectric isolation layer 148, which becomes parts of dies 120′ and wafer 120.

Next, backside interconnect structure 152 is formed, which includes dielectric layers 154 and redistribution lines (RDLs) 156. The respective process is illustrated as process 214 in the process flow 200 as shown in FIG. 23. Dielectric layer 154 may include organic dielectric materials (such as Polybenzoxazoles (PBO), polyimide, or the like) or inorganic dielectric materials (such as SiO, SiN, SiOC, SiON, SiC, SiOCN, or the like). The formation process may include depositing a dielectric material, patterning the dielectric material to reveal the underlying conductive features, forming a metal seed layer, forming a plating mask, plating the RDLs 156, removing the plating mask, and removing the exposed portions of the metal seed layer.

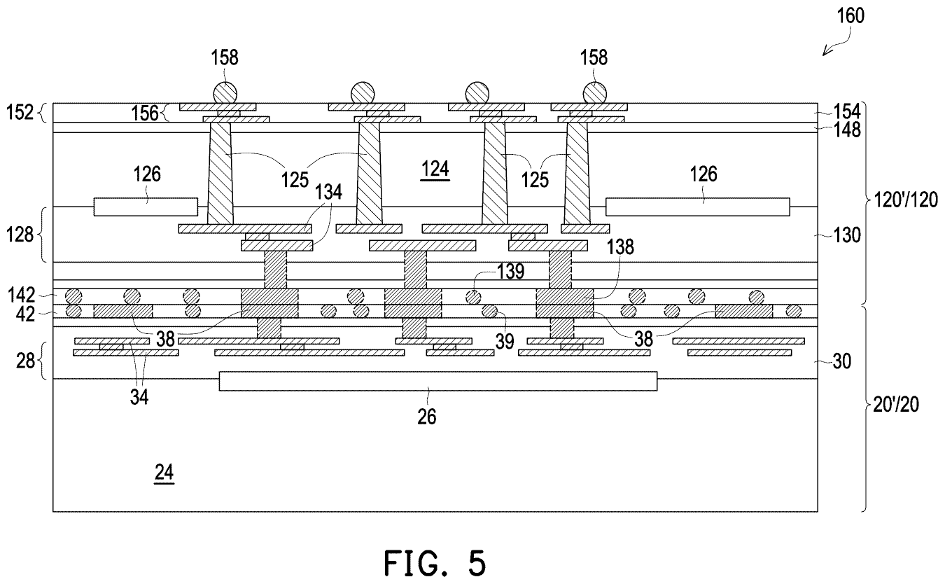

Referring to FIG. 5, electrical connectors 158 (such as solder regions) are formed, hence forming reconstructed wafer 160. The respective process is illustrated as process 216 in the process flow 200 as shown in FIG. 23. Electrical connectors 158 may include solder regions, metal pillars, metal pillars covered with pre-solder layers, or the like. Electrical connectors 158 may comprise copper, and may or may not include titanium, nickel, palladium, or the like.

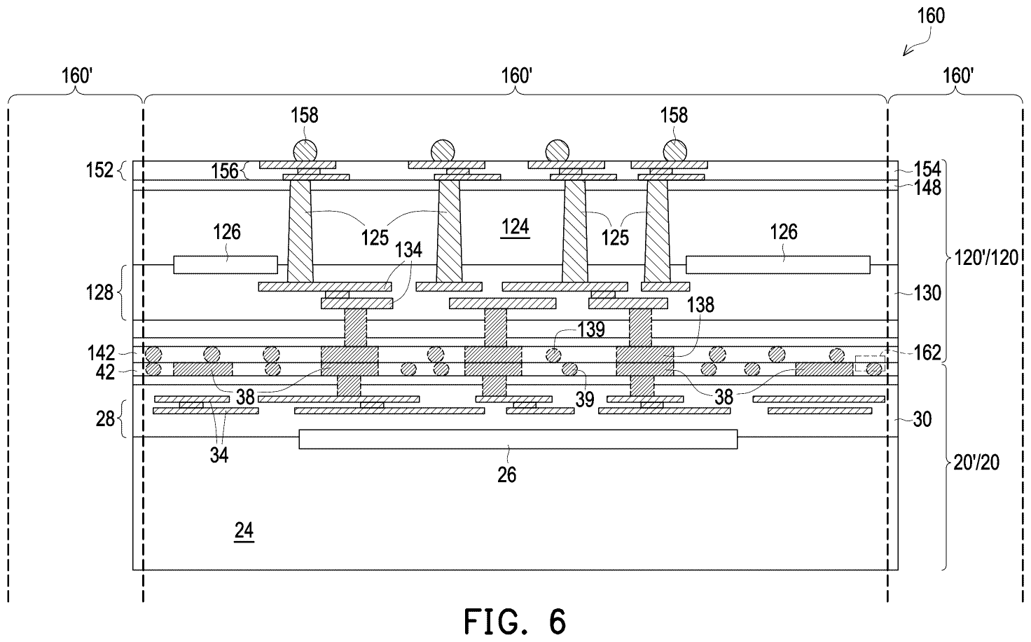

Subsequently, as shown in FIG. 6, a singulation process may be performed to separate reconstructed wafer 160 into discrete packages 160′, which are identical. The singulation process may be performed through a sawing process by using a blade. The respective process is illustrated as process 218 in the process flow 200 as shown in FIG. 23.

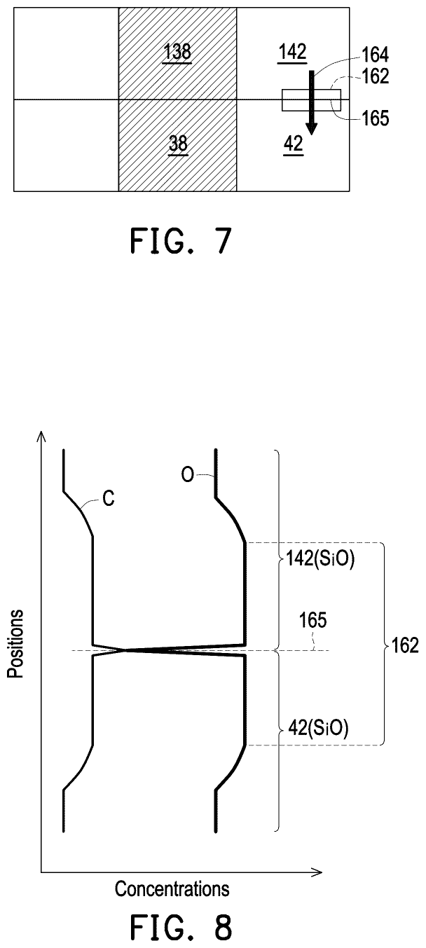

FIG. 7 illustrates an amplified view of a region at the bonding interface as shown FIG. 6. A bonding interface region 162 (also refer to FIG. 6) is illustrated, which includes bond layers 42 and 142 and the bonding interface 165 in between. The details of the composition of the illustrated region are discussed referring to FIGS. 8, 9, and 10.

FIGS. 8, 9, and 10 illustrate the relationships of concentrations of carbon, nitrogen, and oxygen to the positions at the bond interface between wafers 20 and 120 (and between device dies 20′ and 120′). The illustrated positions are shown by arrow 164 in the interface region 162 in FIG. 7. The X-axis shows the concentrations, and in the X-axis, the concentrations increase. The Y-axis shows the positions, with the bond layers 42 and 142 and the bonding interface 165 being marked. The data shown in FIGS. 8, 9, and 10 reflect the Energy Dispersive X-Ray Spectroscopy (EDS) line scan results obtained when HMDS is used to perform the surface treatment on wafer 20 and/or wafer 120.

It is appreciated that the atomic percentages of the elements have the same trend as the concentrations of these elements. For example, the peak concentrations may occur in same positions as peak atomic percentages, and when the concentrations reduce (or increase), the atomic percentages may also reduce (or increase) correspondingly.

FIG. 8 illustrates the results obtained from a sample in which bond layers 42 and 142 are both formed of silicon oxide in accordance with some embodiments. In interface region 162, due to the plasma treatment process 44 (which may cause the growth of silicon oxide at the outermost surface) and the rinsing process (which causes the growth of OH group at the outermost surface), oxygen presents. At bonding interface 165, since CH₃ groups are bonded to silicon atoms, as shown in FIG. 16, the carbon atom percentage increases abruptly, and thus form a peak. Oxygen atomic percent, on the other hand, reduce abruptly and has a valley (minimum value) due to the abrupt increase of the carbon atom percentage (due to that the total atomic percentage of all elements is 100 percent). The illustrated profiles of carbon and oxygen are indications that the surface treatment process 46 has been performed.

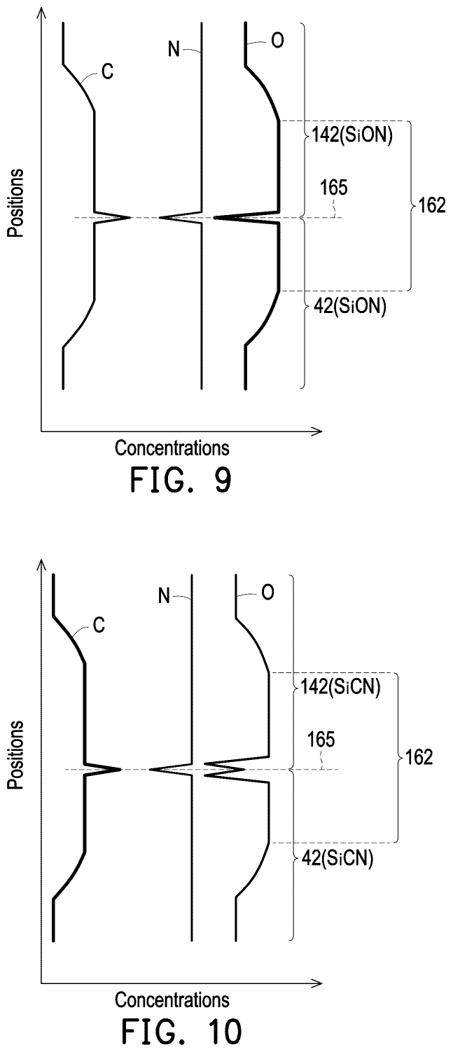

FIG. 9 illustrates the results obtained from a sample in which bond layers 42 and 142 are both formed of SiON in accordance with some embodiments. In interface region 162, due to the plasma treatment process 44 (which may cause the growth of silicon oxide at the outermost surface) and rinsing (which causes the growth of OH group at the outermost surface), oxygen atomic percentage increases in bond interface region 162, and in the regions slight away from bonding interface 165. Some of the N atoms are thus covered by OH groups due to the growth of silicon oxide, and thus nitrogen atomic percentage has a valley (minimum value, reduction) at bonding interface 165.

On the other hand, as also shown in FIG. 16, since CH₃ groups exist, the carbon atom percentage increases abruptly at bonding interface 165, and thus forms a peak as shown in FIG. 9. Oxygen atomic percent, on the other hand, reduce abruptly and has a valley due to the abrupt increase of the carbon atom percentage at bonding interface 165. The illustrated profiles of carbon, nitrogen and oxygen are indications that the surface treatment process 46 has been performed.

FIG. 10 illustrates the results obtained from a sample in which bond layers 42 and 142 are both formed of SiCN in accordance with some embodiments. In interface region 162, due to the plasma treatment process 44 (which may cause the growth of silicon oxide at the outermost surface) and rinsing (which causes the growth of OH group at the outermost surface), oxygen atomic percentage increases at bonding interface 165. Some of the N atoms and C atoms are thus covered by OH groups due to the growth of silicon oxide, and thus nitrogen atomic percentage and the C atomic percentages have valleys (minimum values, reduction) at bonding interface 165.

On the other hand, as also shown in FIG. 16, since CH₃ groups are added at bonding interface 165, the carbon atom percentage increases abruptly, and thus form a peak at bonding interface 165, which peak is also in the valley of the carbon atomic percentage. Accordingly, the carbon atomic percentage shows double-valley reduction in the interface region 162, but has a peak at bonding interface 165. Oxygen atomic percent, on the other hand, increases abruptly and has a peak. The illustrated profiles of carbon, nitrogen and oxygen are indications that the surface treatment process 46 has been performed.

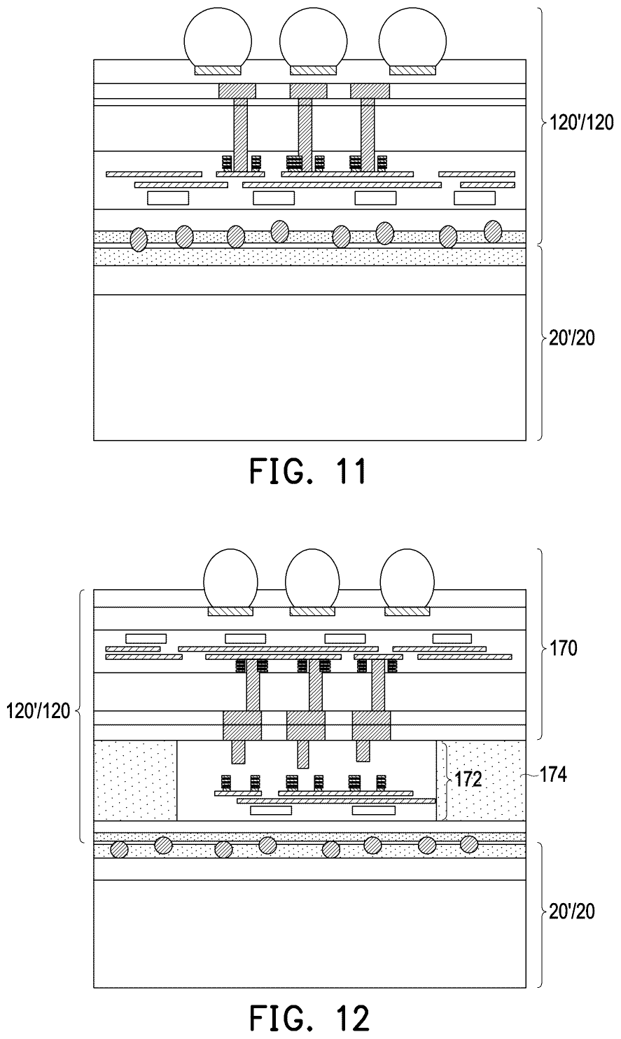

FIGS. 11 through 15 illustrate some embodiments, in which different combinations of types of wafers are bonded to each other. The treatment processes 44 and 46 as shown in FIGS. 1 and 2 may be applied to either one, or both, of the illustrated wafers as shown in FIGS. 11 through 15. FIG. 11 illustrates an embodiment in which wafer 20 comprises a carrier wafer, and wafer 120 comprises a device wafer including TSVs therein.

FIG. 12 illustrates an embodiment in which wafer 20 comprises a carrier wafer 20, and wafer 120 comprises a reconstructed wafer. The reconstructed wafer 120 include device wafer 170, and device dies 172 bonding to device wafer 170. Device dies 172 are in the gap-filling dielectric regions 174.

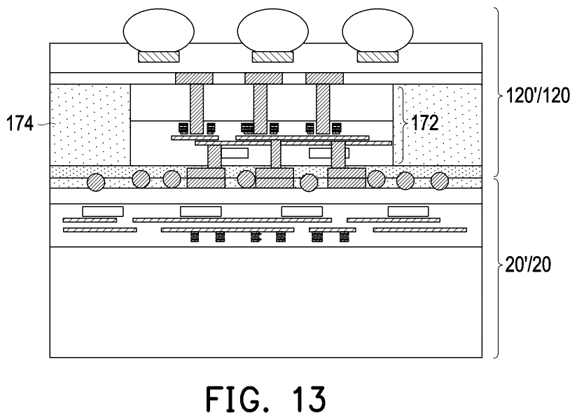

FIG. 13 illustrates an embodiment in which wafer 20 comprises a device wafer 20, and wafer 120 comprises a reconstructed wafer 120. The reconstructed wafer 120 include device wafer 170, and device dies 172 bonding to device wafer 170. Device dies 172 are in the gap-filling dielectric regions 174.

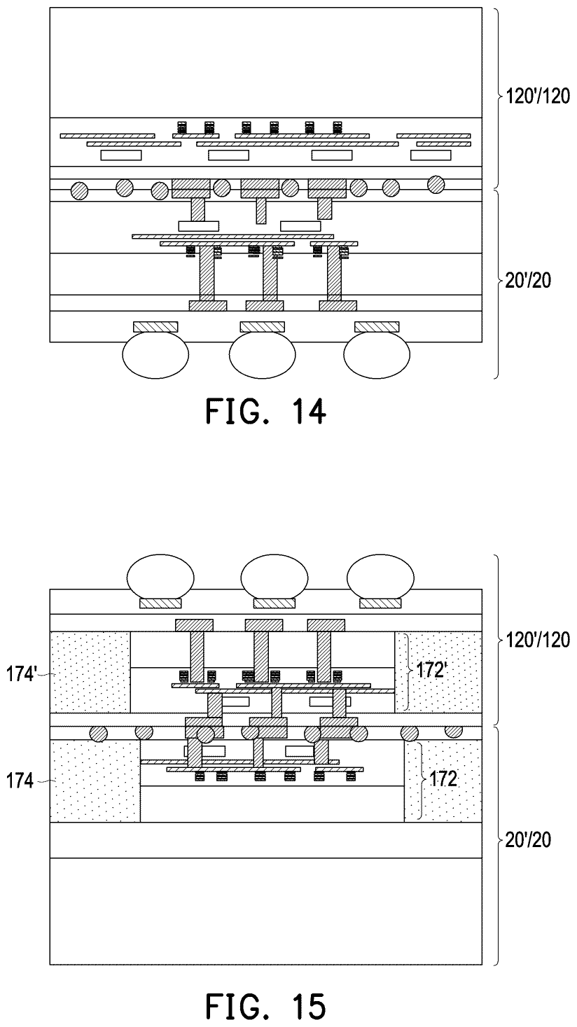

FIG. 14 illustrates an embodiment in which wafer 20 comprises a device wafer 20, and device wafer 120 bonding to device wafer 20.

FIG. 15 illustrates an embodiment in which wafer 20 comprises a reconstructed wafer including device dies 172 therein, and reconstructed wafer 120 bonding to reconstructed wafer 20. The reconstructed wafer 20 and 120 includes device dies 172 and 172′, respectively, which are in gap-fill regions 174 and 174′, respectively.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By performing surface treatment processes on wafers, the wafers, when pre-bonded, have slowed bond wave speed. The distortion of the wafers is thus reduced.

In accordance with some embodiments of the present disclosure, a method comprises performing a plasma treatment on a first wafer; performing a first treatment process on the first wafer, wherein the first treatment process results in the first wafer to be more hydrophobic than before the first treatment process; pre-bonding the first wafer to a second wafer through wafer-to-wafer bonding; and performing an annealing process to bond the first wafer to the second wafer. In an embodiment, the first treatment process is configured to result in a bond wave speed to be reduced, and wherein the bond wave speed is a propagation speed of a bond wave of the pre-bonding. In an embodiment, the first treatment process is performed using HMDS.

In an embodiment, the first treatment process is performed by conducting a hot steam generated from the HMDS to the first wafer. In an embodiment, the first treatment process is performed globally to an entirety of a bond surface of the first wafer. In an embodiment, the first treatment process comprises: masking a first portion of the first wafer; and performing a local treatment using the HMDS on a second portion of the first wafer. In an embodiment, the first treatment process is performed using APTES. In an embodiment, the first treatment process is performed using MPTMS. In an embodiment, the method further comprises performing a second treatment process on the second wafer, wherein the second treatment process results in the second wafer to be more hydrophobic than before the second treatment process.

In accordance with some embodiments of the present disclosure, a structure comprises a first package component comprising a first dielectric layer; and a second package component comprising a second dielectric layer joined to the first dielectric layer, wherein the first dielectric layer and the second dielectric layer comprise an interface region comprising: a first portion of the first dielectric layer; and a second portion of the second dielectric layer, wherein the interface region comprises a first carbon concentration, and wherein the first portion of the first dielectric layer and the second portion of the second dielectric layer form an interface, and the interface has a second carbon concentration higher than the first carbon concentration, and wherein the second carbon concentration is a peak carbon concentration.

In an embodiment, the interface region further comprises two minimum carbon concentrations, with a first one of the two minimum carbon concentrations being in the first portion of the first dielectric layer, and a second one of the two minimum carbon concentrations being in the second portion of the second dielectric layer. In an embodiment, both of the first dielectric layer and the second dielectric layer comprise SiCN. In an embodiment, the interface region comprises a higher oxygen concentration, and wherein the interface has a minimum oxygen concentration lower than the higher oxygen concentration.

In an embodiment, the interface region further comprises a higher nitrogen concentration, and wherein the interface has a minimum nitrogen concentration lower than the higher nitrogen concentration. In an embodiment, the first package component and the second package component are joined to each other with bonds that comprise fusion bonds. In an embodiment, the bonds that join the first package component to the second package component further comprises metal-to-metal direct bonds.

In accordance with some embodiments of the present disclosure, a structure comprises a first device die comprising a first silicon-comprising dielectric layer; and a second device die comprising a second silicon-comprising dielectric layer joined to the first silicon-comprising dielectric layer to form a bonding interface, wherein the first silicon-comprising dielectric layer and the second silicon-comprising dielectric layer comprise: carbon having a peak carbon concentration at the bonding interface, wherein carbon concentrations reduce in an interface region and in directions pointing away from the bonding interface, and wherein the interface region comprises the bonding interface and parts of the first silicon-comprising dielectric layer and the second silicon-comprising dielectric layer; and nitrogen having a minimum concentration at the bonding interface, wherein nitrogen concentrations increase in the interface region and in directions the direction pointing away from the bonding interface.

In an embodiment, the first silicon-comprising dielectric layer and the second silicon-comprising dielectric layer comprise SiCN. In an embodiment, the carbon has two minimum carbon concentrations on opposite sides of the bonding interface. In an embodiment, the structure further comprises oxygen having a peak oxygen concentration at the bonding interface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
performing a plasma treatment on a first wafer;
performing a first treatment process on the first wafer, wherein the first treatment process results in the first wafer to be more hydrophobic than before the first treatment process;
pre-bonding the first wafer to a second wafer through wafer-to-wafer bonding; and
performing an annealing process to bond the first wafer to the second wafer.

2. The method of claim 1, wherein the first treatment process is configured to result in a bond wave speed to be reduced, and wherein the bond wave speed is a propagation speed of a bond wave of the pre-bonding.

3. The method of claim 1, wherein the first treatment process is performed using Hexamethyldisilazane (HMDS).

4. The method of claim 3, wherein the first treatment process is performed by conducting a hot steam generated from the HMDS to the first wafer.

5. The method of claim 3, wherein the first treatment process is performed globally to an entirety of a bond surface of the first wafer.

6. The method of claim 3, wherein the first treatment process comprises:
masking a first portion of the first wafer; and
performing a local treatment using the HMDS on a second portion of the first wafer.

7. The method of claim 1, wherein the first treatment process is performed using Aminopropyltriethoxysilane (APTES).

8. The method of claim 1, wherein the first treatment process is performed using (3-mercaptopropyl) trimethoxysilane (MPTMS).

9. The method of claim 1 further comprising performing a second treatment process on the second wafer, wherein the second treatment process results in the second wafer to be more hydrophobic than before the second treatment process.

10. A structure comprising:
a first package component comprising a first dielectric layer; and
a second package component comprising a second dielectric layer joined to the first dielectric layer, wherein the first dielectric layer and the second dielectric layer comprise an interface region comprising:
a first portion of the first dielectric layer; and
a second portion of the second dielectric layer, wherein the interface region comprises a first carbon concentration, and wherein the first portion of the first dielectric layer and the second portion of the second dielectric layer form an interface, and the interface has a second carbon concentration higher than the first carbon concentration, and wherein the second carbon concentration is a peak carbon concentration.

11. The structure of claim 10, wherein the interface region further comprises two minimum carbon concentrations, with a first one of the two minimum carbon concentrations being in the first portion of the first dielectric layer, and a second one of the two minimum carbon concentrations being in the second portion of the second dielectric layer.

12. The structure of claim 11, wherein both of the first dielectric layer and the second dielectric layer comprise SiCN.

13. The structure of claim 10, wherein the interface region comprises a higher oxygen concentration, and wherein the interface has a minimum oxygen concentration lower than the higher oxygen concentration.

14. The structure of claim 13, wherein the interface region further comprises a higher nitrogen concentration, and wherein the interface has a minimum nitrogen concentration lower than the higher nitrogen concentration.

15. The structure of claim 10, wherein the first package component and the second package component are joined to each other with bonds that comprise fusion bonds.

16. The structure of claim 15, wherein the bonds that join the first package component to the second package component further comprises metal-to-metal direct bonds.

17. A structure comprising:
a first device die comprising a first silicon-comprising dielectric layer; and
a second device die comprising a second silicon-comprising dielectric layer joined to the first silicon-comprising dielectric layer to form a bonding interface, wherein the first silicon-comprising dielectric layer and the second silicon-comprising dielectric layer comprise:
carbon having a peak carbon concentration at the bonding interface, wherein carbon concentrations reduce in an interface region and in directions pointing away from the bonding interface, and wherein the interface region comprises the bonding interface and parts of the first silicon-comprising dielectric layer and the second silicon-comprising dielectric layer; and
nitrogen having a minimum concentration at the bonding interface, wherein nitrogen atomic percentages increase in the interface region and in directions the direction pointing away from the bonding interface.

18. The structure of claim 17, wherein the first silicon-comprising dielectric layer and the second silicon-comprising dielectric layer comprise SiCN.

19. The structure of claim 18, wherein the carbon has two minimum carbon concentrations on opposite sides of the bonding interface.

20. The structure of claim 18 further comprising oxygen having a peak oxygen concentration at the bonding interface.
